(19) United States
(12) Patent Application Publication
(10) Pub. No.: US 2015/0228585 A1
(43) Pub. Date: Aug. 13, 2015

(54) SELF-FORMING BARRIER INTEGRATED WITH SELF-ALIGNED CAP

(71) Applicant: GLOBALFOUNDRIES Inc., Grand Cayman (KY)

(72) Inventors: Ming HE, Slingerlands, NY (US); Larry ZHAO, Niskayuna, NY (US)

(73) Assignee: GLOBALFOUNDRIES Inc., Grand Cayman (KY)

(21) Appl. No.: 14/176,716

(22) Filed: Feb. 10, 2014

(51) Int. Cl. H01L 23/532; H01L 21/285; H01L 21/3213; H01L 23/528; H01L 21/768

(52) U.S. Cl. CPC H01L 23/53238; H01L 23/528; H01L 23/5329; H01L 21/76843; H01L 21/7685; H01L 21/32134; H01L 21/28518; H01L 21/28568; H01L 21/28556

(57) ABSTRACT

A method of forming a self-forming barrier with an integrated self-aligned metal cap, wherein the barrier is formed on all surfaces of the via, and the resulting device are provided. Embodiments include forming a metal line in a first Si-based dielectric layer; removing a portion of the metal line; depositing a metal cap over the metal line; forming a second Si-based dielectric layer on the first Si-based dielectric layer and the metal cap; forming a cavity in the second Si-based dielectric layer down to the metal cap; and depositing a barrier-forming layer on side and bottom surfaces of the cavity and over the second Si-based dielectric layer.

### TECHNICAL FIELD

The present disclosure relates to the manufacture of semiconductor devices with copper (Cu) interconnect structures. The present disclosure is particularly applicable to the formation of self-forming barriers in 20 nanometer (nm) through 7 nm technology nodes and beyond.

### BACKGROUND

To provide electrical conductivity between layers in a semiconductor device, a hole or via may be formed through interlayer dielectrics (ILDs). The via is then lined with a barrier layer and filled with an electrically conductive material such as Cu to provide electrical conductivity between the layers. However, most known self-forming barrier techniques only address applying the barrier to via sidewalls without considering the via bottom, which can reduce the electro-migration (EM) benefit of the short-length effect when compared to a conventional tantalum nitride (TaN) barrier.

For example, a known approach to forming a metal self-forming barrier involves forming a manganese (Mn) or CuMn alloy seed by chemical vapor deposition (CVD), as illustrated in FIGS. 1A through 1C. In particular, a metal line 101, e.g., Cu, is formed in a substrate 103, as depicted in FIG. 1A. Next, a capping layer 105 is formed on the metal line 101 and the substrate 103. An ultra-low-k (ULK) dielectric material 107 is then formed on the capping layer 105. Subsequently, a cavity 111 is formed in the ULK dielectric material 107 and capping layer 105 down to the metal line 101. Thereafter, a barrier layer 109, e.g., a dielectric or CVD of Mn or CuMn, is formed on the sidewalls and bottom of the cavity 111.

Adverting to FIG. 1B, a metal layer 113, e.g., Cu, is then formed in the cavity 111. As a result of a subsequent thermal annealing process, the barrier layer 109 reacts with the ULK dielectric material 107 to form a manganese silicate (MnSiₓO_{y}) interface layer 115 as depicted in FIG. 1C. However, during annealing, the interface layer 115 can easily diffuse into the metal line 101, leaving no barrier at the via bottom as depicted by the dashed circle 117. The same would be true for a barrier formed from a dielectric. Consequently, the EM benefit of the short-length effect can be lost, potentially reducing the EM performance of the structure.

Another known approach involves implementing an in-level liner process such as either performing a selective CVD liner deposition before depositing a self-forming barrier or performing a flash dry etch by either physical vapor deposition (PVD) or gas cluster ion beam (GCIB) before depositing a self-forming barrier. However, selective CVD liner deposition requires very high selectivity, e.g., only at the via bottom and not on the sidewalls, because any residual deposition on the sidewalls may affect the subsequent self-forming barrier process/formation. Further, covering a via bottom by PVD/GCIB flash requires careful calibration of the deposition thickness. For example, if a PVD/GCIB flash causes any deposition/overhang on the top of the feature corner, this may cause a smaller top critical dimension (CD) before the self-forming barrier is formed, which may negatively affect the process window for the later Cu seed/plating process.

A need therefore exists for methodology enabling formation of a self-forming barrier that protects both the sidewalls and the bottom of a via against unwanted diffusion and/or EM, and the resulting device.

### SUMMARY

An aspect of the present disclosure is a method of forming a self-forming barrier with an integrated self-aligned metal cap.

Another aspect of the present disclosure is a device including a self-forming barrier with an integrated self-aligned metal cap, wherein the barrier is formed on all surfaces of the via, including the bottom surface.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including: forming a metal line in a first silicon-based (Si-based) dielectric layer; removing a portion of the metal line; depositing a metal cap over the metal line; forming a second Si-based dielectric layer on the first Si-based dielectric layer and the metal cap; forming a cavity in the second Si-based dielectric layer down to the metal cap; and depositing a barrier-forming layer on side and bottom surfaces of the cavity and over the second Si-based dielectric layer.

Aspects of the present disclosure include removing the portion of the metal line by a wet etch process. Further aspects include wet etching the portion of the metal line to a depth of 2 nm to 50 nm. Another aspect includes the metal cap being formed of Ta, cobalt (Co), cobalt/tungsten/phosphorous (CoWP), ruthenium (Ru), or Mn. Additional aspects include depositing the metal cap by PVD or by CVD. Other aspects include planarizing the metal cap and the first Si-based dielectric layer by chemical mechanical polishing (CMP). Further aspects include planarizing the metal cap to a thickness greater than 2 nm and less than 50 nm. Another aspect includes depositing the barrier-forming layer by CVD or atomic layer deposition (ALD). Additional aspects include the barrier-forming layer being formed of Mn, manganese nitride (MnN), or Co/Mn. Other aspects include depositing the barrier-forming layer to a thickness of 0.5 nm to 5 nm. Further aspects include forming the metal cap of Mn; and depositing the barrier-forming layer to a thickness greater than 3 nm. Another aspect includes forming the first and second Si-based dielectric layers of silicon dioxide (SiO₂) or an ULK dielectric material. Other aspects include depositing the barrier-forming layer at a temperature of 100° C. to 400° C. Further aspects include the barrier-forming layer reacting with the second Si-based dielectric layer to form a self-forming barrier layer of MnSiₓO_{y}. Another aspect includes thermal annealing the barrier-forming layer after CVD or ALD at a temperature of 100° to 400° in a vacuum, forming gas, or argon (Ar) protection gas to form the self-forming barrier layer of MnSiₓO_{y}.

Another aspect of the present disclosure is a device including: a metal line in a first Si-based dielectric layer; a metal cap formed on top of the metal line; a second Si-based dielectric layer over the metal cap and first Si-based dielectric layer; a cavity formed through the second Si-based dielectric layer down to the metal cap; and a MnSiₓO_{y} barrier layer formed on sidewalls and on the second Si-based dielectric layer. Aspects of the device include the Si-based dielectric layer being formed of an ULK dielectric material or SiO₂. Other aspects include the MnSiₓO_{y} barrier layer having a thickness of 0.5 nm to 5 nm, and the cavity having a bottom width of 10 nm to 100 nm. Further aspects include the metal cap being formed of Ta, Co, CoWP, Ru, or Mn.

Another aspect of the present disclosure is a method including: forming a metal line in a first ULK dielectric layer; removing a portion of the metal line by a wet etch process; depositing a metal cap of Ta, Co, CoWP, Ru, or Mn over the metal line and the first ULK dielectric layer; planarizing the metal cap and the first ULK dielectric layer by chemical metal polishing; forming a second ULK dielectric layer on the first ULK dielectric layer and the metal cap; forming a cavity in the second ULK dielectric layer down to the metal cap, the cavity having a bottom width of 10 nm to 100 nm; and conformally forming a Mn, MnN, or Co/Mn barrier-forming layer in the cavity and over the second ULK dielectric layer by CVD or ALD at 100° C. to 400° C., wherein the Mn, MnN, or Co/Mn barrier-forming layer reacts with the second ULK dielectric layer to form MnSiₓO_{y} barrier layer during CVD or ALD or during a subsequent thermal annealing at 100° to 400° after CVD or ALD.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIGS. 1A through 1C schematically illustrate sequential steps of a background method of forming a self-forming barrier using a dielectric or CVD of Mn; and

FIGS. 2 through 10 schematically illustrate sequential steps of a method of forming a self-forming barrier integrated with a self-aligned metal cap, in accordance with an exemplary embodiment.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of device reliability degradation, e.g., reducing EM performance, attendant upon forming a dielectric barrier or CVD of a Mn barrier, wherein during an annealing step, Mn at the bottom of a via can easily diffuse into bulk Cu, leaving no liner at the via bottom. By forming a self-forming barrier with an integrated self-aligned metal cap, a barrier is formed on all surfaces of the via, including the bottom surface.

Methodology in accordance with embodiments of the present disclosure includes forming a metal line in a first Si-based dielectric layer. A portion of the metal line is removed. A metal cap is deposited over the metal line. A second Si-based dielectric layer is formed on the first Si-based dielectric layer and the metal cap. A cavity is formed in the second Si-based dielectric layer down to the metal cap. A barrier-forming layer is formed on side and bottom surfaces of the cavity and over the second Si-based dielectric layer.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

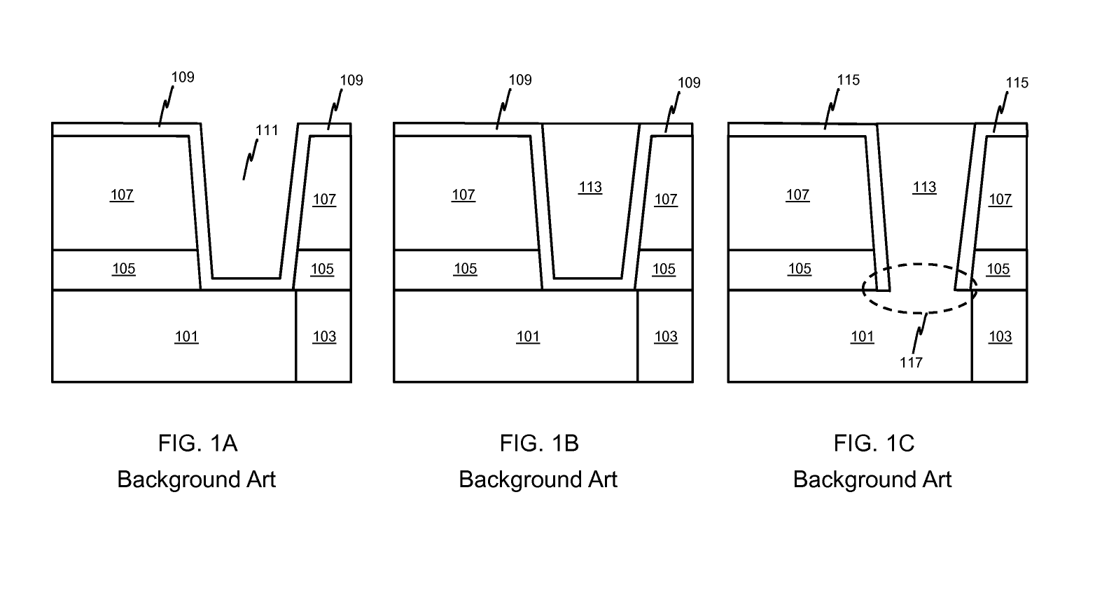

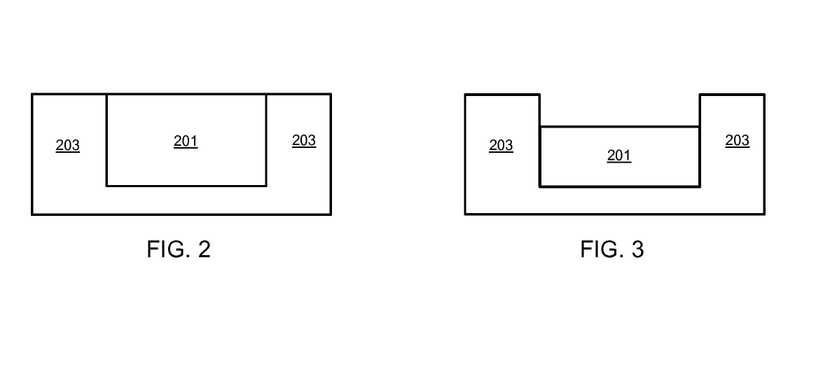

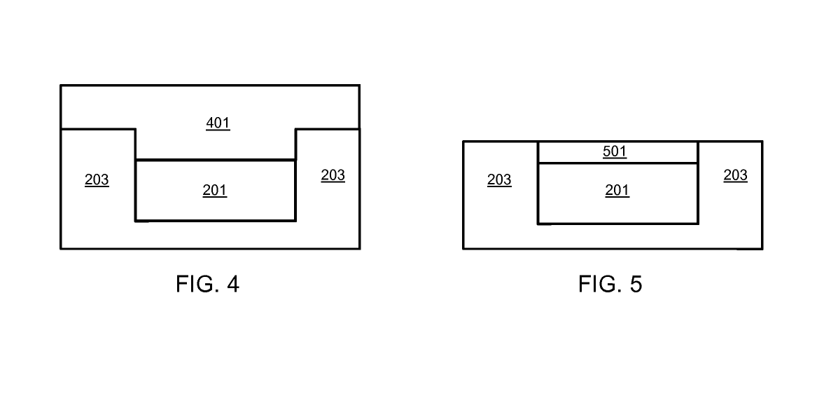

FIGS. 2 through 10 schematically illustrate sequential steps of a method of forming a self-forming barrier with an integrated self-aligned metal cap, in accordance with an exemplary embodiment. Adverting to FIG. 2, similar to the background processes discussed with respect to FIGS. 1A through 1C, a metal line 201, e.g., Cu, is formed in a first Si-based dielectric layer 203, e.g., SiO₂ or a ULK dielectric material. Next, a portion of the metal line 201, e.g., 2 nm to 50 nm, is removed by a wet etch process, forming a recess as illustrated in FIG. 3. Adverting to FIG. 4, a metal cap layer 401, e.g., Ta, Co, CoWp, Ru, or Mn, is deposited over the metal line 201 and the first Si-based dielectric layer 203, by PVD or CVD. Thereafter, the metal cap layer 401 and the first Si-based dielectric layer 203 are planarized by CMP, forming a metal cap 501, as depicted in FIG. 5. More specifically, the metal cap layer 401 is planarized to form a metal cap 501 having a final thickness greater than 2 nm and less than 50 nm.

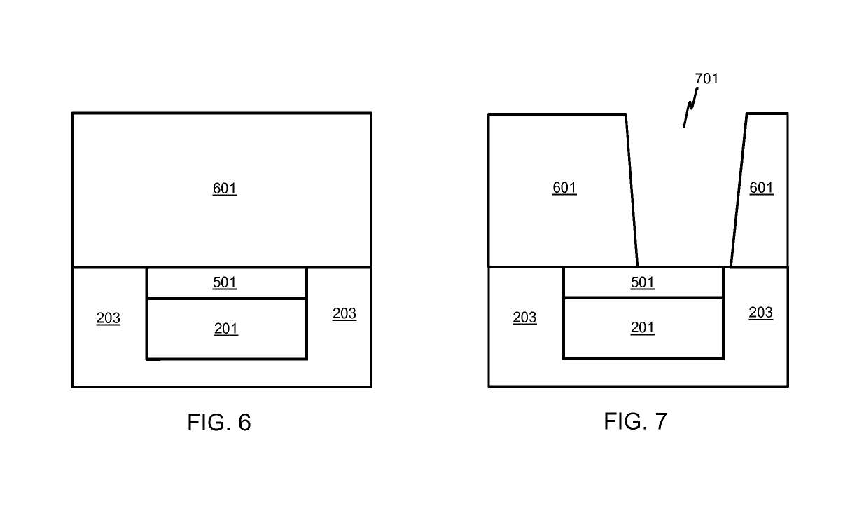

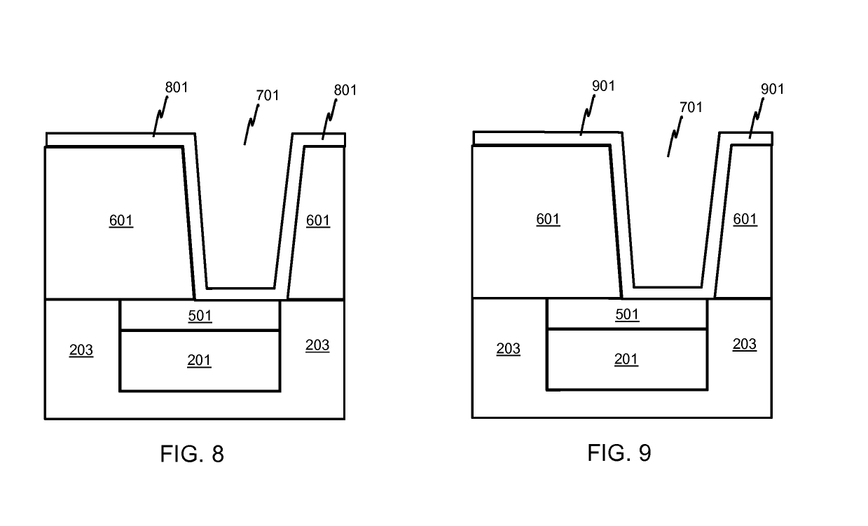

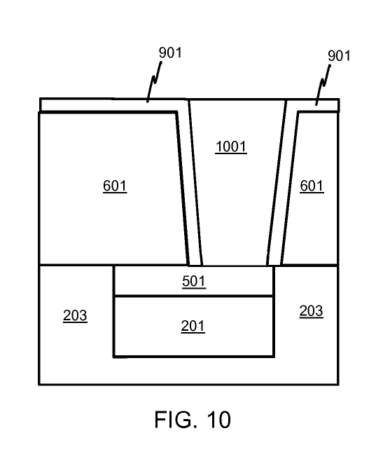

Adverting to FIG. 6, a second Si-based dielectric layer 601, e.g., SiO₂ or a ULK dielectric material, is deposited on the first Si-based dielectric layer 203 and the metal cap 501. Next, a cavity 701 is formed in the second Si-based dielectric layer 601 down to the metal cap 501, as illustrated in FIG. 7. Adverting to FIG. 8, a barrier-forming layer 801, e.g., Mn, MnN, or Co/Mn, is deposited for example by CVD or ALD at a temperature of 100° C. to 400° C. and to a thickness of 0.5 nm to 5 nm. More specifically, if the metal cap 501 is formed of Mn, then the barrier-forming layer 801 is deposited to a thickness greater than 3 nm. As a result of the deposition temperature, the barrier-forming layer 801 reacts with the SiO₂ or ULK dielectric material 601 to form a MnSiₓO_{y} self-forming barrier layer 901 as depicted in FIG. 9. Alternatively, after CVD or ALD, the MnSiₓO_{y} self-forming barrier layer 901 is formed by thermal annealing the barrier-forming layer 801 at a temperature of 100° C. to 400° C. in a vacuum, forming gas, or Ar protection gas (not shown for illustrative convenience). Adverting to FIG. 10, a metal layer 1001, e.g., Cu, is then formed in the cavity 701 on top of the MnSiₓO_{y} self-forming barrier layer 901.

The embodiments of the present disclosure can achieve several technical effects including forming a liner at a via bottom, thereby eliminating Mn diffusion into the Cu metal line, which in turn improves EM performance. In addition, the via-bottom liner formation process can be separated from the self-forming barrier process by deconvoluting the two processes into different metal levels, which frees the process window for both via bottom liner and self-forming barrier processes. Embodiments of the present disclosure enjoy utility in various industrial applications as, for example, microprocessors, smart phones, mobile phones, cellular handsets, set-top boxes, DVD recorders and players, automotive navigation, printers and peripherals, networking and telecom equipment, gaming systems, and digital cameras. The present disclosure therefore enjoys industrial applicability in any of various types of integrated circuits including copper interconnect structures, particularly for 20 nm through 7 nm technology nodes and beyond.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

1. A method comprising:
forming a metal line directly in a first silicon-based (Si-based) dielectric layer without any layer between the metal line and the first Si-based dielectric layer;
removing a portion of the metal line;
depositing a metal cap over the metal line;
forming a second Si-based dielectric layer on the first Si-based dielectric layer and the metal cap;
forming a cavity in the second Si-based dielectric layer down to the metal cap; and
depositing a barrier-forming layer on side and bottom surfaces of the cavity and over the second Si-based dielectric layer.

2. The method according to claim 1, comprising removing the portion of the metal line by a wet etch process.

3. The method according to claim 2, comprising wet etching the portion of the metal line to a depth of 2 nanometers (nm) to 50 nm.

4. The method according to claim 1, wherein the metal cap comprises tantalum (Ta), cobalt (Co), cobalt/tungsten/phosphorous (CoWP), ruthenium (Ru), or manganese (Mn).

5. The method according to claim 1, comprising depositing the metal cap by plasma vapor deposition (PVD) or by chemical vapor deposition (CVD).

6. The method according to claim 1, further comprising planarizing the metal cap and the first Si-based dielectric layer by chemical mechanical polishing (CMP).

7. The method according to claim 6, comprising planarizing the metal cap to a thickness greater than 2 nm and less than 50 nm.

8. The method according to claim 1, comprising depositing the barrier-forming layer by CVD or atomic layer deposition (ALD).

9. The method according to claim 8, wherein the barrier-forming layer comprises Mn, manganese nitride (MnN), or Co/Mn.

10. The method according to claim 1, comprising depositing the barrier-forming layer to a thickness of 0.5 nm to 5 nm.

11. The method according to claim 9, comprising:
forming the metal cap of Mn; and
depositing the barrier-forming layer to a thickness greater than 3 nm.

12. The method according to claim 1, comprising forming the first and second Si-based dielectric layers of silicon dioxide (SiO₂) or an ultra-low-k (ULK) dielectric material.

13. The method according to claim 1, comprising depositing the barrier-forming layer at a temperature of 100° C. to 400° C.

14. The method according to claim 13, wherein the barrier-forming layer reacts with the second Si-based dielectric layer to form a self-forming barrier layer of manganese silicate (MnSiOₓ).

15. The method according to claim 14, further comprising thermal annealing the barrier-forming layer after CVD or ALD at a temperature of 100° to 400° in a vacuum, forming gas, or argon (Ar) protection gas to form the self-forming barrier layer of MnSiOₓ.

16. A device comprising:
a metal line directly in a first Si-based dielectric layer without any layer between the metal line and the first Si-based dielectric layer;
a metal cap formed on top of the metal line;
a second Si-based dielectric layer over the metal cap and first Si-based dielectric layer;
a cavity formed through the second Si-based dielectric layer down to the metal cap; and
a manganese silicate (MnSiOₓ) barrier layer formed on sidewalls and on the second Si-based dielectric layer.

17. The device according to claim 16, wherein the Si-based dielectric layer comprises an ultra-low-k (ULK) dielectric material or silicon dioxide (SiO₂).

18. The device according to claim 16, wherein the MnSiOx barrier layer has a thickness of 0.5 nm to 5 nm, and wherein the cavity has a bottom width of 10 nm to 100 nm.

19. The device according to claim 16, wherein the metal cap comprises tantalum (Ta), cobalt (Co), cobalt/tungsten/phosphorous (CoWP), ruthenium (Ru), or manganese (Mn).

20. A method comprising:
forming a metal line directly in a first ultralow-k (ULK) dielectric layer without any layer between the metal line and the first Si-based dielectric layer;
removing a portion of the metal line by a wet etch process;
depositing a metal cap of tantalum, cobalt (Co), Co/tungsten/phosphorous, ruthenium, or manganese (Mn) over the metal line and the first ULK dielectric layer;
planarizing the metal cap and the first ULK dielectric layer by chemical metal polishing;
forming a second ULK dielectric layer on the first ULK dielectric layer and the metal cap;
forming a cavity in the second ULK dielectric layer down to the metal cap, the cavity having a bottom width of 10 nanometers (nm) to 100 nm; and
conformally forming a Mn, MnN, or Co/Mn barrier-forming layer in the cavity and over the second ULK dielectric layer by chemical vapor deposition (CVD) or atomic layer deposition (ALD) at 100° C. to 400° C.,
wherein the Mn, MnN, or Co/Mn barrier-forming layer reacts with the second ULK dielectric layer to form a manganese silicate (MnSiOₓ) barrier layer during CVD or ALD or during a subsequent thermal annealing at 100° to 400° after CVD or ALD.
